(19) United States
(12) Patent Application Publication
(10) Pub. No.: US 2016/0372777 A1
(43) Pub. Date: Dec. 22, 2016

(54) METHOD FOR DETERMINING THE STATE OF CHARGE OF A VANADIUM REDOX FLOW BATTERY

(71) Applicant: UNIVERSITY OF LIMERICK, Limerick (IE)

(72) Inventors: Denis Noel BUCKLEY, Limerick (IE); Xin GAO, Shanghai (CN); Robert Patrick LYNCH, Clare (IE); Martin J. LEAHY, Limerick (IE); Andrea BOURKE, Limerick (IE); Grace FLYNN, Kerry (IE)

(73) Assignee: UNIVERSITY OF LIMERICK, Limerick (IE)

(21) Appl. No.: 15/101,092

(22) PCT Filed: Dec. 2, 2014
(86) PCT No.: PCT/EP2014/076266

§ 371 Date: Jun. 2, 2016

(30) Foreign Application Priority Data
Dec. 2, 2013 (EP) 13195315.0

(51) Int. Cl. H01M 8/18; G01R 31/36; H01M 8/0444; G01N 21/31; H01M 8/20; H01M 8/04537

(52) U.S. Cl. CPC H01M 8/188; H01M 8/20; H01M 8/04604; H01M 8/0444; G01N 21/31; G01R 31/3651; G01N 2021/1748

(57) ABSTRACT

The invention relates to a method for determining V^{IV} or V^{V} concentration in mixtures of V^{IV} and V^{V} solutions, the method comprising the steps of determining the absorbance of the solution at at least one wavelength; and calculating the concentration of the V^{IV} and V^{V} solution based on the absorbance. In one embodiment the V^{IV}, V^{V} and/or total vanadium concentration in a solution is calculated based on the fact that the absorbance at a specific wavelength can be predicted by taking into account the formation of vanadium complexes.

### FIELD

The invention relates to a method for determining the state of charge of a vanadium redox flow battery.

### BACKGROUND

During the charging-discharging process of a vanadium redox flow battery (VRFB), the state of charge (SoC) of the battery is dependent on the amount of V^{II} on the negative side of the battery and the amount of V^{V} on the positive side of the cell. One reason for the necessity to measure the amount of both of these species is because hydrogen evolution and other processes occur in VRFBs, which result in the negative and positive half-cells differing in the amount of vanadium in their respective charged state. Similarly, the transfer of vanadium species through membranes that separate the two halves of each cell of the battery often results over time in significant changes in the total amount of vanadium present on each side of the battery. Therefore, it is necessary to know the mixture ratio and the total amount of vanadium, i.e. it is necessary to know the amount of vanadium in the charged state, of both the positive and negative half-cell so as to be able to determine the remaining charge of the battery. Furthermore, knowledge of the two mixture ratios of the vanadium species can be used to determine when there is a danger of overcharging allowing greater control of the system and prevention of damage to electrodes prior to it occurring.

There are several known ways of measuring the V^{II}/V^{III} and V^{IV}/V^{V} mixture ratios. For instance, it is known that the Nernst equation defines the relationship between the mixture ratio and the potential. This equation is:

$$E = {E}^{0} + \frac{RT}{nF} log ( \frac{[ {V}^{II} ] [ {V}^{V} ]}{[ {V}^{III} ] [ {V}^{IV} ]} )$$

where E⁰ is the equilibrium potential (i.e. the potential is the summation of the formal potential of V^{II}/V^{III} and the formal potential of V^{IV}/V^{V}) in volts (V), R is the universal constant (8.314 J mol⁻¹ K⁻¹), T is the temperature in Kelvin (K), n is the electron-transfer number, F is Faraday's constant (96485 C mol⁻¹), V^{II}/V^{III} is the mixture ratio for the anolyte, and V^{V}/V^{IV} is the mixture ratio for the catholyte. It follows that, as long as the mixture ratios of the two half cells are equal (i.e. as long as V^{II}/V^{III} is equal to V^{V}/V^{IV}) the mixture ratios and therefore the SoC of the battery can be determined. Indeed, the conventional and most used method for determining the SoC of a VRFB is by measuring the open-circuit voltage of the battery. One such example of this method is set out in US Patent Publication No. 2012/022535 in the name of Christensen, which describes a technique that relies on the open-circuit potential of a battery to measure an initial SoC, and then monitors the flow of current while the circuit is closed so as to track changes in the SoC.

One problem with measuring the SoC of a battery by means of its open-circuit voltage is that since the current efficiencies of the two half cells are not the same, it follows that the mixture ratios of the two half cells are rarely the same. An alternative method that is widely used in research to determine the SoC of a VRFB is through the use of reference electrodes placed in the two half cells. Another known method for calculating the SoC is to measure the conductivity of the electrolyte, as disclosed by PCT Patent Publication Number WO 90/03666 in the name of Skyllas-Kazacos. However, both of these techniques also require extra electrodes to be placed within the cell, and can therefore interfere with the operation of the cell.

All of these known methods of calculating the SoC of a VRFB have drawbacks. Firstly, it is not simple to measure the SoC of a half-cell, since small offsets and drifts in the potentials of the electrodes can be equivalent to the change in potential for a significant change in mixture ratio, especially for mixture ratios close to 50%. Furthermore, due to the nature of the electrolyte, the solution in reference electrodes may be easily contaminated. In addition, as these methods are electrochemical, they do not provide an independent reading, in that they will vary in a similar manner to the cell output regardless of whether the variation is due to an actual change in mixture ratio or the presence of impurities, changes in surface states or other issues that alter the behaviour of the electrodes. Furthermore, these methods can interfere with the operation of the battery: e.g. they may increase leakage currents if not engineered into the battery with due care.

Spectroscopy can be used to accurately measure the concentration of species in solution by measuring the absorbance of the solution at different wavelengths. Often such methods are facile since the absorbance at a wavelength and the concentration of a species will vary proportionally. U.S. Pat. No. 7,855,005 in the name of Sahu and PCT Patent Publication Number WO 90/03666 in the name of Skyllas-Kazacos describe methods for determining the SoC of different flow batteries using the linear relationship between absorbance and mixture ratio at specific wavelengths.

Spectroscopy can also be used to monitor the vanadium mixture ratio of species as long as the absorbance is proportional to the concentration of each species. In this regard, it has been found that the mixture ratio of the negative electrolyte or the amount of V^{II} (i.e. in V^{II}/V^{III} mixtures) can be determined using the linear response of absorbance to mixture ratio at several wavelengths. (PCT Patent Number WO 90/03666 in the name of Skyllas-Kazacos). The absorbance of a vanadium solution of only V^{IV} or V^{V} varies linearly with vanadium concentration. However, despite there being wavelengths where the absorbance due to V^{IV} is significantly greater than the absorbance due to V^{V} and vice versa (as is shown in FIG. 3), high concentration mixtures of V^{IV} and V^{V} solution result in non-linear variations of absorbance with respect to the percentage of V^{V} (or V^{IV}) for any particular wavelength, as is shown in FIG. 5a. Dilution of the electrolyte reduces this non-linear behaviour towards that of a linear behaviour between absorbance and mixture ratio, as is shown in FIG. 5d Thus, at the vanadium concentrations used, a linear relationship between mixture ratio and absorbance does not exist for the positive electrolyte of VRFBs due to the formation of a complex between V^{IV} and V^{V} species.

Chinese Patent Publication No, CN 102 539 362 describes the dilution of solutions to gain solutions that are of low enough concentration that the effect of complex formation is removed, in order that the solutions can be analyzed by spectroscopy in a conventional manner.

To overcome this lack of a linear relationship between absorbance and mixture ratio for the positive electrolyte in vanadium solutions, it is known to use a set of calibration spectra for comparing against spectra taken from operating VRFBs (L. Lie, et al., J. Appl. Electrochem. 42, 1025 (2012)). However, it will be appreciated that this requires a set of calibration spectra for the specific solution, as well as a large amount of computational processing power to compare the operational spectrum to the calibration spectra. Furthermore, due to changes in the overall vanadium concentration during operation of a VRFB—caused by the diffusion of species across the proton exchange membrane and volume change due to transfer of water the calibrated spectra become less valid with each charge-discharge cycle of the battery.

Therefore, there exists a need to provide an improved method for determining the mixture ratio of V^{IV} and V^{V} solutions from absorption spectra.

### SUMMARY OF THE INVENTION

According to the invention there is provided, as set out in the appended claims, a method for determining V^{IV} or V^{V} concentration in mixtures of V^{IV} and V^{V} solutions, the method comprising the steps of: determining the absorbance (or other optical property) of the solution at at least one wavelength; and calculating the concentration of the V^{IV} and/or V^{V} solution based on the absorbance (or other optical property).

In one embodiment, the overall vanadium concentration in the solution is known and where a non-proportional relationship exists between the vanadium species concentration and absorbance due to the presence of complexes between V^{IV} and V^{V}, wherein the step of calculating the concentration of the V^{IV} and/or V^{V} solution based on the absorbance comprises the steps of:

comparing the absorbance against a look-up graph of absorbance versus fraction of V^{V} for at least one wavelength and for the same overall vanadium concentration; and
estimating the fraction of V^{IV} and/or V^{V} in the solution from the comparison.

In one embodiment the method further comprises:

determining the absorbance of the solution at at least one alternative wavelength;
comparing the absorbance against a look-up graph of absorbance versus fraction of V^{V} for the at least one alternative wavelength and for the same overall vanadium concentration; and
estimating the fraction of V^{IV} and/or V^{V} in the solution from the comparison performed at the at least one wavelength and the comparison performed at the at least one alternative wavelength.

In one embodiment the method further comprises estimating the fraction of V^{IV} and/or V^{V} in the solution from the comparison performed at the at least one wavelength and based on one or more of: positive state of charge, SoC, negative SoC, cell voltage or the change in absorbance when charging or discharging of the electrolyte.

In one embodiment the look-up graph of absorbance versus fraction of V^{V} for a given wavelength is constructed by the steps of:

determining for the given wavelength the absorbance of a V^{IV} solution of a known concentration; and
determining for the given wavelength the absorbance of a calibration sample of V^{IV}/V^{V} solution of a known mixture ratio and a known concentration.

In one embodiment two calibration samples of V^{IV}-V^{V} mixtures of known concentration and mixture ratio are used for the construction of the look-up graph.

In one embodiment a solution whose V^{IV}/V^{V} mixture ratio can be changed in a controlled manner, and wherein the calibration comprises changing the mixture ratio and comparing the change in mixture ratio to the absorbance of the solution.

In one embodiment, the V^{IV}/V^{V} mixture ratio is changed in a controlled manner by passing current through the electrode of a half-cell.

In one embodiment the overall vanadium concentration is known and where a non-proportional relationship exists between vanadium species concentration and absorbance due to the presence of complexes between V^{IV} and V^{V}, wherein the step of calculating the concentration of the V^{IV} and/or V^{V} solution based on the absorbance comprises the steps of:

determining the ratio of excess absorbance for a pair of specific wavelengths; and
estimating the concentration of V^{IV} and/or V^{V} by solving simultaneous equations based on the determined ratio of excess absorbance for the pair of specific wavelengths.

In one embodiment the overall vanadium concentration is not known and, wherein the concentration of vanadium or the concentration of the V^{IV} and/or V^{V} solution is calculated by:

determining the ratio of excess absorbance for two pairs of specific wavelengths; and
estimating the concentration of vanadium, V^{IV} and/or V^{V} by solving simultaneous equations based on the determined ratio of excess absorbance for the two pairs of specific wavelengths.

In one embodiment the equation for the simultaneous equations comprises

$${A}_{y nm} \approx \frac{{δ}_{y nm}^{*} ( {A}_{x nm} - {ε}_{x nm}^{V} ( [ {V}^{IV} ] + [ {V}^{IV} ] ) L )}{{δ}_{x nm}^{*}} + {ε}_{y nm}^{{V}^{IV}} [ {V}^{IV} ] L$$

where A_{y nm} is absorbance at y nanometres and A_{x nm} is the absorbance at x nanometres, δ is a constant that is dependent on the extinction coefficient and the concentration of the complex, ε_{λ}^{V}^{^{IV}} and ε_{λ}^{V}^{^{V}} are the extinction coefficients for the V^{IV} and V^{V} species, respectively, at the wavelength (λ) of interest, [V^{IV}] and [V^{V}] are the V^{IV} and V^{V} concentration, respectively, before the formation of a complex, and L is the pathlength of the light through the solution

In one embodiment the excess absorbance at a specific wavelength is determined by:

measuring the absorbance at a specific wavelength of a solution of known vanadium concentration;
calculating the predicted absorbance at the specific wavelength that would occur if no complexes were present; and
subtracting this calculated predicted absorbance value from the measured absorbance value.
In one embodiment the step of measuring the excess absorbance at a specific wavelength of a solution of known vanadium concentration further comprises:
   constructing a first look-up graph at the specific wavelength of absorbance versus fraction of V^{V};
   constructing a second graph similar to the first graph of the predicted absorbance at the specific wavelength versus fraction of V^{V} that would occur if no complexes were present;
   and constructing a look-up graph of the difference in absorbance between the first graph and the second graph versus fraction of V^{V}, wherein this difference corresponds to the excess absorbance.

In one embodiment the step of measuring the absorbance at a specific wavelength of a solution of known concentration comprises measuring the absorbance at a specific wavelength of a calibrated solution of known concentration.

In one embodiment the step of calculating the predicted absorbance at the specific wavelength that would occur if no complexes were present is based on the extinction coefficients of V^{IV} and V^{V}.

In one embodiment the absorbance of the solution at at least one alternative wavelength is used to determine or verify the fraction or concentration of either V^{IV} or V^{V}

In one embodiment there is provided a method for calculating the state of charge, SoC, of a vanadium redox flow battery, VRFB, comprising a V^{II}-V^{III} solution and a V^{IV}-V^{V} solution, the method comprising the steps of:

calculating the amount of V^{V} in the V^{IV}-V^{V} solution by the method above;
calculating the amount of V^{II} in the V^{II}-V^{III} solution;
determining whether the calculated amount of V^{V} or the calculated amount of V^{II} is lower in value; and
determining the SoC of the VRFB from this lower value.

In one embodiment there is provided a method for calculating the SoC of an electrochemical cell comprising of a V^{IV} and V^{V} solution as the catholyte or anolyte in one half of the cell and a second half-cell whose remaining charge can be estimated.

The method may be used for a group of electrochemical cells of the same type either in series or in parallel.

The method may be used for electrochemical cells of different types either in series or in parallel where some or all of the half-cells use mixtures of V^{IV} and V^{V} in solution.

In one embodiment the concentration is calculated based on the fact that the fraction of V^{IV} or V^{V} with respect to overall vanadium, at low overall vanadium concentrations, is proportional to the absorbance. It will be appreciated that while absorbance is described other optical properties can be used to implement the invention.

The invention provides a method to determine the State of Charge (SoC) of a Vanadium Redox Flow Battery (VRFB) or similar device through the determination of the remaining amount of the charged species of both the catholyte and the anolyte.

In one embodiment there is provided a step of diluting the vanadium solution to a lower concentration prior to measuring absorbance values and calculating the mixture ratio.

In one embodiment there is provided a vanadium solution comprising of V^{IV} and V^{V} species is charged and/or discharged by a half-cell of an electrochemical cell or similar device where a second half-cell or group of half-cells undergo the same or a known fraction of charging and/or discharging is also present in the system and state of charge of both halves of the system were know at a previous time, the mixture ratio is calculated by:

determining the absorbance at at least one wavelength for the solution in the second half of the system;
estimating the state of charge of the second half of the system;
determining how much charge has passed since the earlier time; and
determining the state of charge or remaining V^{V} concentration of the V^{IV}-V^{V} solution.

In one embodiment there is provided a method other than determining the absorbance of the second solution is use to determine the change in state of charge of the second solution.

In one embodiment a correction is made in calculating the amount of charge that is passed from the change in state of charge of the second half of the system by taking into account the coulombic efficiency of the second half of the system.

In one embodiment the change in state of charge is determined from the amount of charge that has passed taking into account the coulombic efficiency of the V^{IV}-V^{V} reactions.

In one embodiment the vanadium solution comprises of V^{II} and V^{III} or V^{III} and V^{IV} species, the method comprising the steps of:

determining the absorbance of the solution at at least one wavelength; and
calculating the fraction or concentration of the vanadium species of interest based on the concentration is proportional to the absorbance.

In one embodiment the overall vanadium concentration is known, and the mixture ratio is calculated by:

determining the absorbance due to V^{IV}, V^{V} or the complex from the absorbance at one or more wavelengths; and
determining concentration and/or fraction of overall vanadium of the V^{IV} and/or V^{V} by calculation;

In one embodiment the V^{IV} (or V^{V}) concentration is known, and the mixture ratio is calculated by:

determining the absorbance due to (V^{IV},) V^{V} or the complex from the absorbance at one or more wavelengths; and
determining concentration and/or fraction of overall vanadium of the V^{IV} and/or V^{V} by calculation;

In one embodiment the overall vanadium concentration is known and the fraction or concentration of V^{IV} or V^{V} is calculated by:

determining the absorbance of the solution at at least one wavelength;
comparing the absorbance to a look-up graph or calculated fitted trend line for absorbance versus fraction of either V^{IV} or V^{V}; and
estimating the concentration of V^{IV} or V^{V}.

In one embodiment the absorbance of the solution at at least one alternative wavelength is used to determine or verify the fraction or concentration of either V^{IV} or V^{V}

In one embodiment the concentration or fraction of V^{IV} or V^{V} is calculated by:

determining the ratio of excess absorbance of the solution at two wavelengths;
estimating the absorbance that would be present if no complex had formed due either to the V^{IV} or V^{V} by compensating for the excess absorbance due to the presence of a complex; and
estimating the concentration of V^{IV} or V^{V}.

In one embodiment the excess absorbance at a given wavelength is determined by subtracting the sum of V^{IV} and V^{V} absorbance values from the absorbance values for the solution at the given wavelength.

In one embodiment the excess absorbance at a given wavelength is estimated by multiplying the excess absorbance at another wavelength by the respective characteristic ratio of excess absorbance.

In one embodiment the overall vanadium concentration is known or can be estimated, and the mixture ratio is calculated by:

determining the absorbance or the excess absorbance at one or more wavelengths

In one embodiment the absorbance or excess absorbance is used to determine the concentration of V^{IV}, V^{V}, complex or total vanadium

In one embodiment the overall vanadium concentration is unknown, and the fraction or concentration of a vanadium species is calculated by:

determining the ratio of excess absorbance of the solution at one or more pairs of wavelengths;
estimating both the V^{IV} and the V^{V} concentration that would be present if no complex had formed in the solution based on the ratio of excess absorbance; and/or
determining the fraction V^{IV} and V^{V} based on estimated V^{IV} and V^{V} concentration.

In one embodiment there is provided the further step of determining the overall vanadium concentration based on the estimated V^{IV} or the V^{V} concentration.

In one embodiment the change in absorbance or excess absorbance with respect to charge passed is used to determine the fraction of V^{IV}, V^{V}, and/or complex and/or the concentration of V^{IV}, V^{V}, complex and/or total vanadium.

In one embodiment there is provided the step of calculating the state of charge, SoC, of a vanadium redox flow battery, VRFB, comprising a V^{II}-V^{III} solution, anolyte, and a V^{IV} and V^{V} solution, catholyte, the method comprising the steps of:

calculating the fraction or concentration of V^{V} in solution by the method above;
calculating the fraction or concentration of V^{II} in the V^{II}-V^{III} solution; and
determining the SoC of the VRFB from these fractions and the charge capacities of both the V^{II}-V^{III} and V^{IV}-V^{V} solutions or from these concentrations and volumes of the solution.

In one embodiment there is provided the step of calculating the mixture ratio of the V^{II}-V^{III} solution comprises:

determining the absorbance of the solution at a wavelength; and
calculating the concentration or fraction of V^{II} in the V^{II}-V^{III} solution based on the absorbance.

In one embodiment there is provided a step of calculating the state of charge, SoC, of an electrochemical cell comprising of a V^{IV} and V^{V} solution as the catholyte or anolyte and second half-cell whose remaining charge can be estimated.

In one embodiment the method can be used for a group of electrochemical cells of the same type either in series or in parallel.

In one embodiment the method can be used for electrochemical cells of different types either in series or in parallel where some or all of the half-cells use mixtures of V^{IV} and V^{V} in solution.

### BRIEF DESCRIPTION OF THE DRAWINGS

The invention will be more clearly understood from the following description of an embodiment thereof, given by way of example only, with reference to the accompanying drawings, in which:—

FIG. 1 shows an example of a method for determining state-of-charge (SoC) of a vanadium redox flow battery (VRFB);

FIG. 2 shows an example of a method for determining mixture ratio of the positive electrolyte facilitating the determination of the SoC of a VRFB;

FIG. 3 shows the absorption spectra at concentrations of 1.54 mol dm⁻³, 0.77 mol dm⁻³ and 0.15 mol dm⁻³ for (a) V^{II}, (b) V^{III}, (c), V^{IV} and (d) V^{V} solutions. All solutions were prepared by charging or discharging, where necessary, from VOSO₄ solutions of the required concentration in supporting electrolytes of 3 mol dm⁻³ H₂SO₄;

FIG. 4 (a) shows absorbance as a function of wavelength for mixtures of 1.5 mol dm⁻³ V^{II} and V^{III} solutions shown in FIG. 3 and (b) as a function of ratio of V^{II} to overall vanadium;

FIG. 5 shows graphs of the effect of dilution on absorbance values at 760 nm as a function of ratio of V^{V} to overall vanadium. The overall vanadium concentration of the solutions are: (a) 1.24, (b) 0.77, (c) 0.30, and (d) 0.06 mol dm⁻³. The original solution was prepared by charging the vanadium in a 1.55 mol dm⁻³ VOSO₄ solution in a supporting electrolyte of 3 mol dm⁻³ H₂SO₄ to the V^{V} state;

FIG. 6 shows the absorbance, predicted absorbance and the difference between the two (i.e. excess absorbance) (a) as a function of wavelength and (b) as a function of ratio of V^{V} to overall vanadium for mixtures of V^{IV} and V^{V} solutions shown in FIG. 5;

FIG. 7 shows graphs that allow the experimental (dots) and predicted (line) absorbance as a function of percentage V^{V} at (a) 760 nm, (b) 670 nm, (c) 521 nm, and (d) 450 nm to be compared (for the same mixtures as in FIG. 6);

FIG. 8 shows the absorption spectra for different mixtures of V^{IV} and V^{V} solutions of 1.24 mol dm⁻³ vanadium, as shown in FIG. 6. The mixtures shown are for V^{V} of approximately 0, 10, 30, 51, 66, 89 and 100% of total vanadium;

FIG. 9 (a) shows a graph of excess absorbance value as a function of wavelength for the different mixtures of 1.24 mol dm⁻³ vanadium solutions similar to those shown in FIG. 8, while FIG. 9 (b) shows a graph of the ratio of excess absorbance at 760 or 450 nm to that at 520 nm as a function of percentage V^{V}. Triangles and circles represent A*(760 nm)/A*(520 nm) and A*(450 nm)/A*(520 nm), respectively. Overall vanadium concentrations of 1.55, 1.24, 0.77 and 0.30 mol dm⁻³ are represented by black, blue, red and green symbols, respectively; and

FIG. 10 is a table showing a comparison of the prepared and estimated (via absorption spectroscopy) V^{V} percentages for 1.24 mol dm⁻³ mixtures using equations similar to Eq. (4) set out in the specification. The A*_{760 nm}/A*_{520 nm} and A*_{450 nm}/A*_{520 nm} values are taken from FIG. 9b to be 1.09 and 0.50, respectively. The extinction coefficients ε_{520 nm}^{V}=0.52 mol dm⁻³ cm⁻¹, ε_{760 nm}^{V}^{^{IV}}=17.8 mol dm⁻³ cm⁻¹ an ε_{450 nm}^{V}^{^{V}}=7.04 mol dm⁻³ cm⁻¹ were calculated from V^{IV} and V^{V} spectra and the pathlength (L) was 0.1 cm.

### DETAILED DESCRIPTION OF THE DRAWINGS

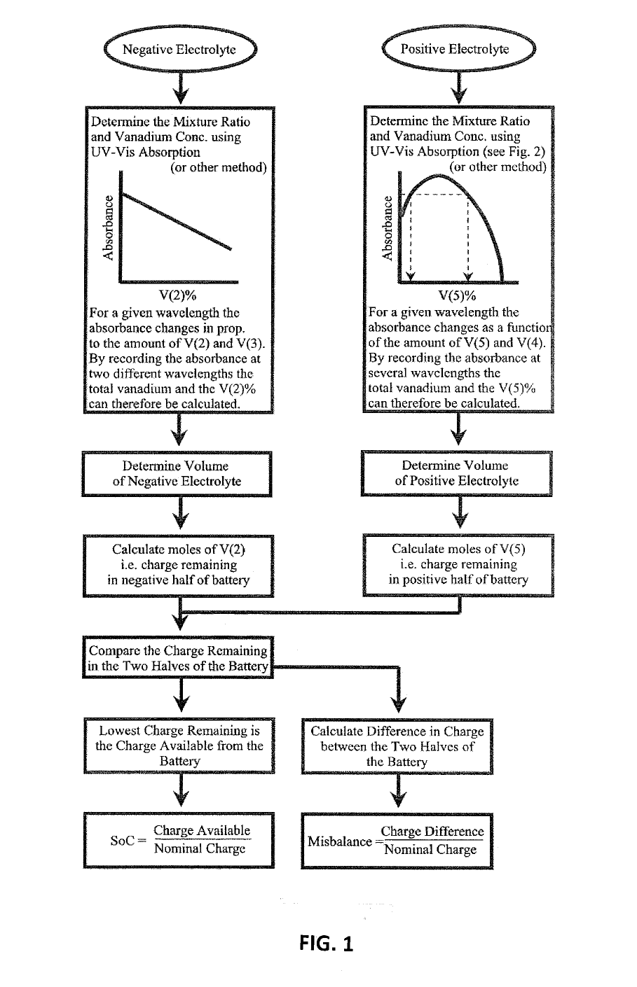

The present invention describes a sequence of methods to determine the amount of vanadium species in the charged state, i.e. the concentration of V^{II} and V^{V} in V^{II}/V^{III} and V^{IV}/V^{V} mixed solutions, respectively. These methods allow the state of charge (SoC) of both the positive and negative half-cells of a vanadium redox flow cell (VRFC) to be calculated, which in turn enables the SoC of the VRFC, as well as the imbalance in the state of the two half-cells to be determined, as shown in FIG. 1.

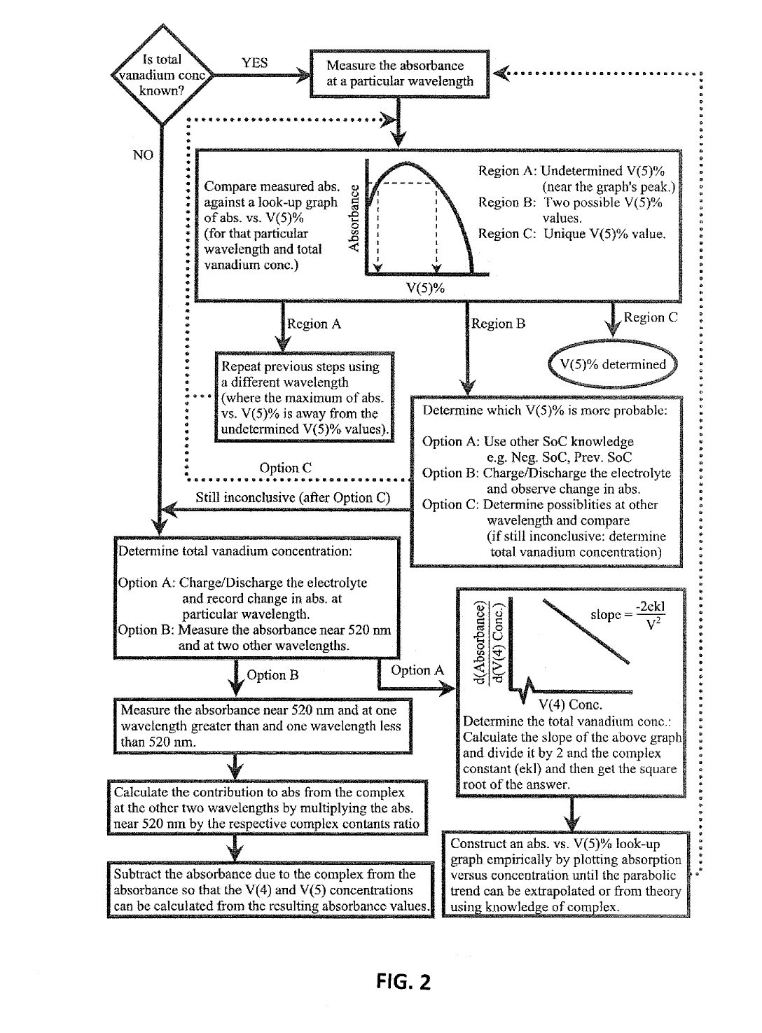

More particularly, the methods of the present invention enable the accurate measurement of the fraction of vanadium in the V^{V} state (positive electrolyte state-of-charge) in mixtures of V^{IV} and V^{V} solutions (i.e. the positive electrolyte or catholyte), see FIG. 2, thus overcoming the problem of there being a non-linear relationship between absorbance and V^{V} fraction for the positive electrolyte in vanadium solutions. Once the measurement of the V^{V} fraction in V^{IV}/V^{V} solutions has been obtained by means of the methods of the present invention, the results can be combined with standard spectroscopic methods or alternative methods (such as those described in the background to the invention section) for measuring the fraction of vanadium in the V^{II} state (negative electrolyte state-of-charge) in the negative electrolyte (i.e. V^{II}/V^{III} mixtures). This in turn enables the SoC and other parameters of VRFBs and other batteries and devices that use mixtures of V^{IV} and V^{V} solutions to be determined.

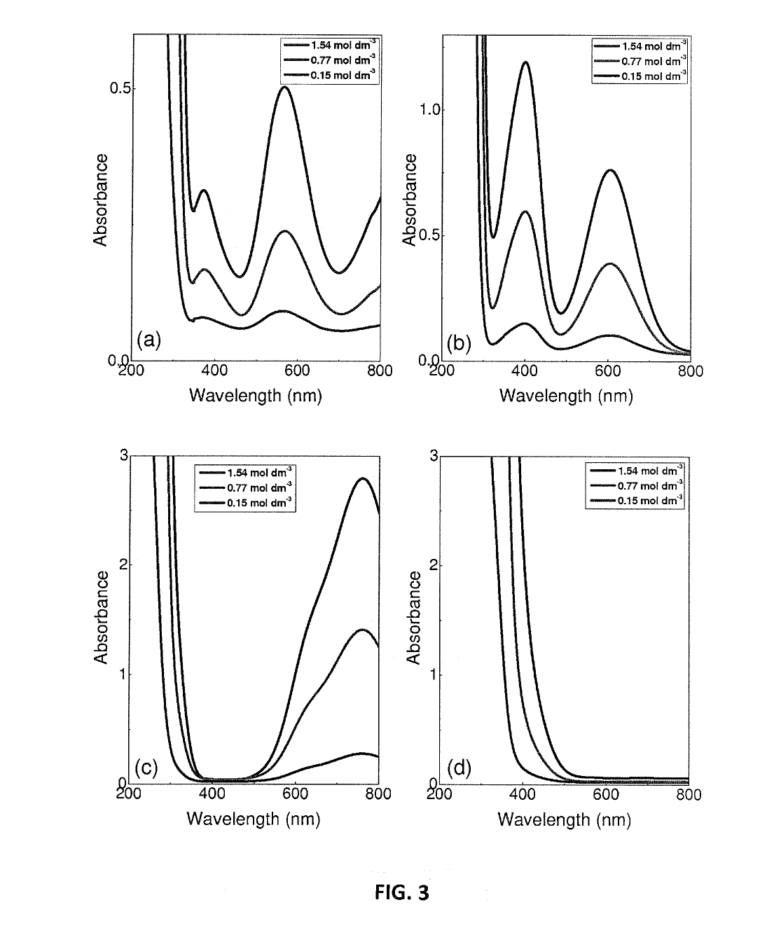

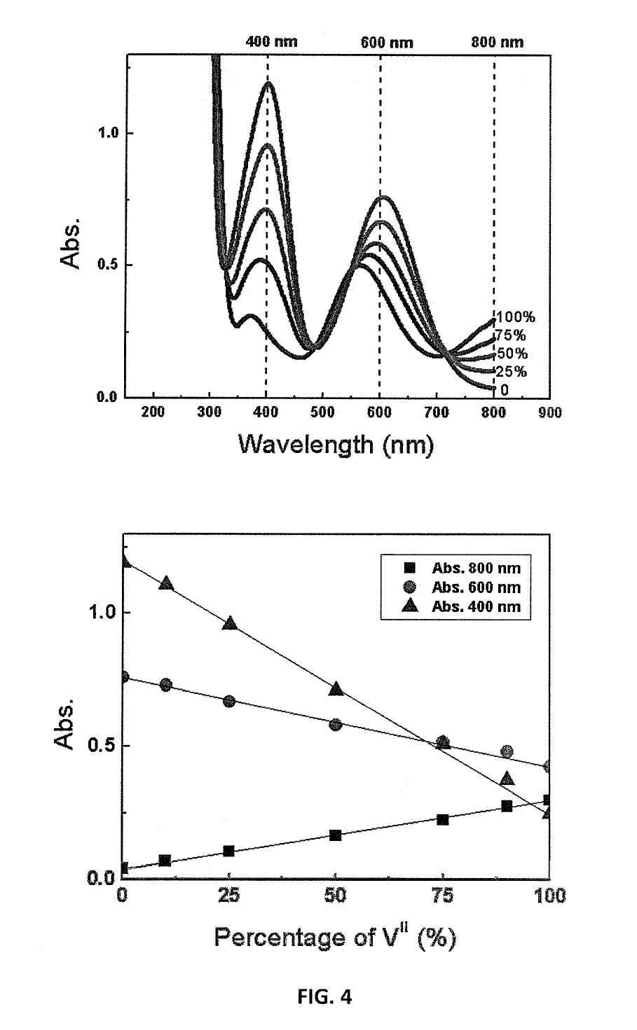

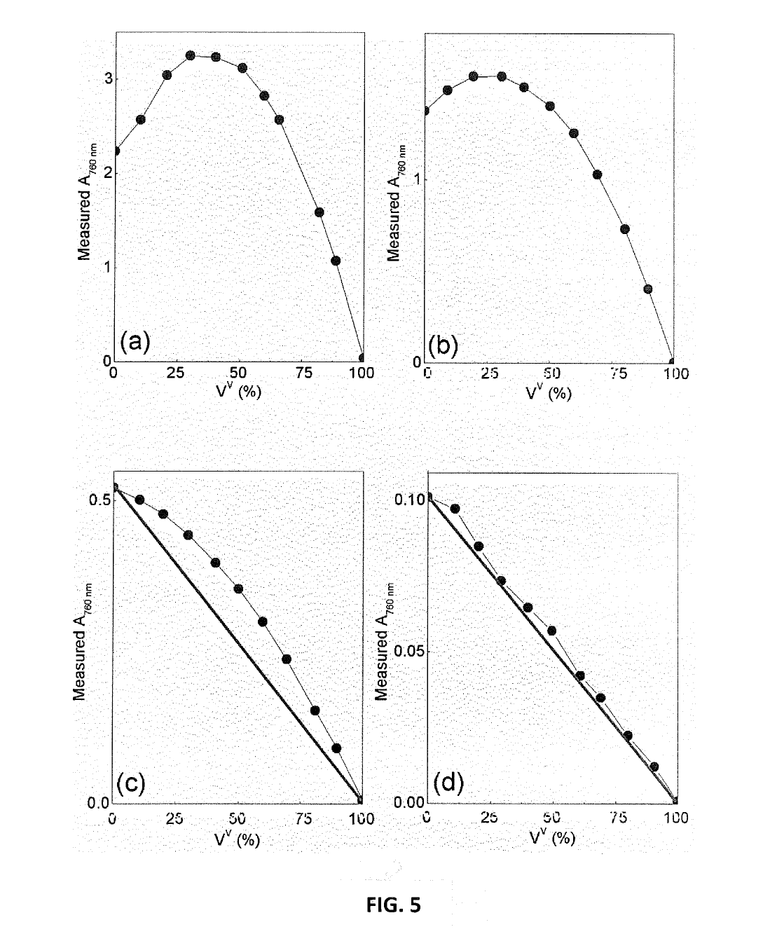

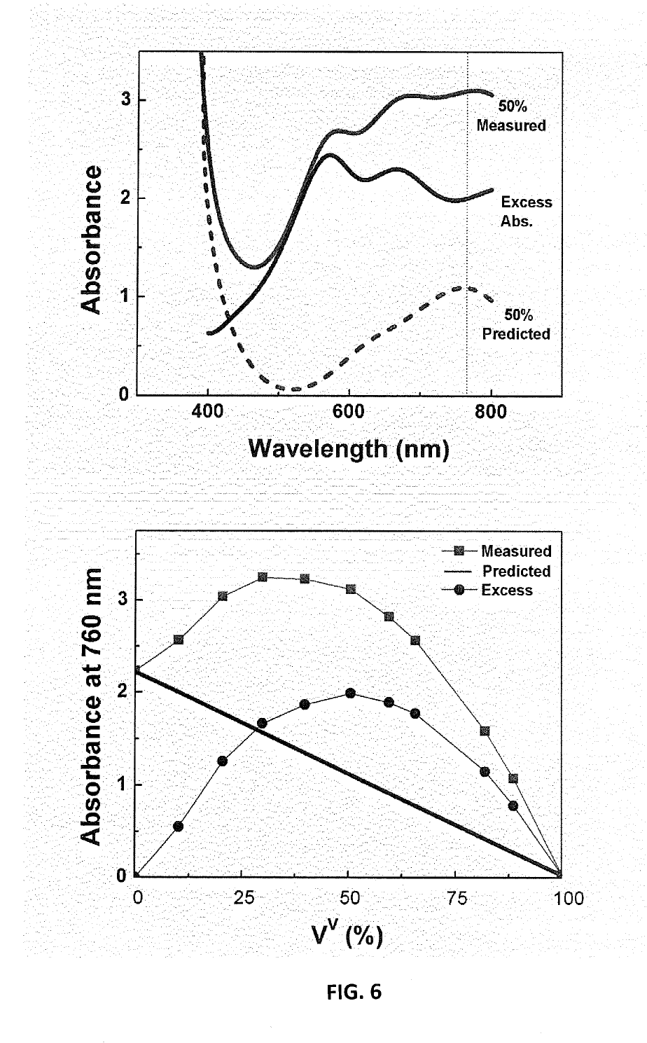

As shown in FIG. 3 the four vanadium species—i.e. the four vanadium oxidation states that exist in solution: V^{II}, V^{III}, V^{IV} and V^{V}—have significantly different absorption spectra. In a solution that contains a mixture of two of these vanadium species the absorption spectrum is composed of components due to the two respective species. Therefore as long as the species do not interact to form complexes the mixture's spectrum should be simply the addition of the absorbance due to each species. This is the case for V^{II}/V^{III} (as shown in FIG. 4), V^{III}/V^{IV} and dilute V^{IV}/V^{V} mixtures (as shown in FIG. 5d). However, for V^{IV}/V^{V} mixtures of the concentrations used in VRFBs the absorbance values are the sum of three absorbance components, i.e., as shown in FIG. 6, the components due to absorbance by V^{IV} and V^{V} species and the absorbance due to a complex of the two species. It follows that for solutions of increasing overall vanadium concentration the relationship between absorbance and fraction of V^{V} goes from being linear to being parabolic, as shown in FIG. 5. Unfortunately the concentration of the complex is never significant enough to allow it to be determined making it non straight-forward to determine the fraction of V^{V} in a concentrated vanadium solution from the absorbance.

FIG. 2 shows a method for determining the fraction of V^{V} and hence to determine the SoC of the positive electrolyte: If the overall concentration of the vanadium in the solution is known the absorbance can be measured at a particular wavelength and compared to a look-up graph of absorbance versus fraction of V^{V} (for that wavelength), as shown for 760 nm in FIG. 6b. The look-up graph can be compiled empirically by measuring the absorbance of several solutions of known mixture ratio and the same overall vanadium concentration and then by fitting a quadratic curve to the resulting set of data (which is usually a parabolic curve in cases where the ratio of the concentration of the complex to the product of the concentrations of V^{IV} and V^{V} is very small). Alternatively, the graph can be constructed from theory and calibrated using a V^{IV} solution of known concentration (which may not necessarily be the same as the solution to be examined) and one solution of known mixture ratio and the same overall vanadium concentration as the electrolyte that is being examined.

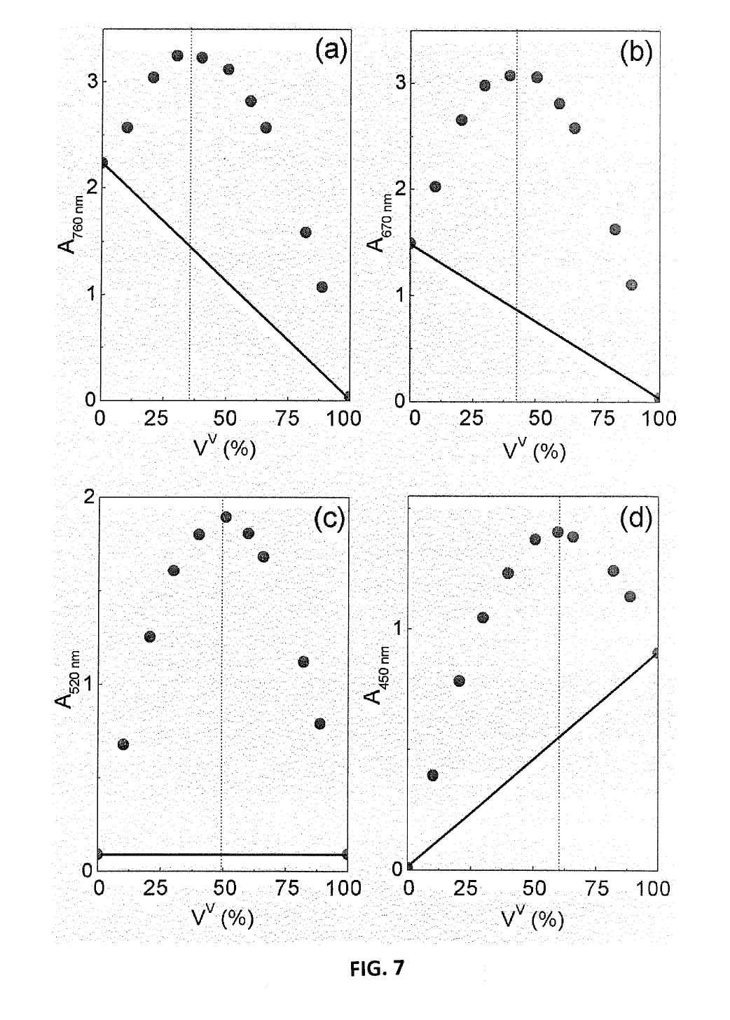

There are three valid results, as shown in FIG. 2, for the comparison of the absorbance of the positive electrolyte to its respective look-up graph:
1. In a first case, the absorbance of the electrolyte could be close to the maximum, resulting in a wide range of possible values for the fraction of V^{V}, i.e. an inaccurate result. In such cases the absorbance at a second wavelength (the maximum absorbance value of which occurs outside the range of possible values for fraction of V^{V}), as shown in FIG. 7, can be examined;
2. In a second case, due to the quadratic dependence of absorbance on the fraction of V^{V}, the measured absorbance of the electrolyte can be attributed to solutions of two different mixture ratios. Such a case can be solved by looking at the absorbance at a second wavelength. At the second wavelength up to two possible V^{V} fractions will be given as possibilities. However, only one of these possibilities will agree with the possible V^{V} fractions that could result in the absorbance at the first wavelength tested. Furthermore, instead of looking at the absorbance at a second wavelength other options; such as using previous knowledge of positive SoC, negative SoC or cell voltage or monitoring of change in absorbance with charging or discharging of the electrolyte; can indicate which of the results for V^{V} fraction is valid; or
3. In a third case, the absorbance measured at the first wavelength could have given a unique result therefore allowing the positive SoC to be determined from the absorbance at one wavelength.

Since the absorbance at each wavelength will give one, two or a range of results, several wavelengths can be used to determine the accuracy of the result or the need to recalibrate the system.

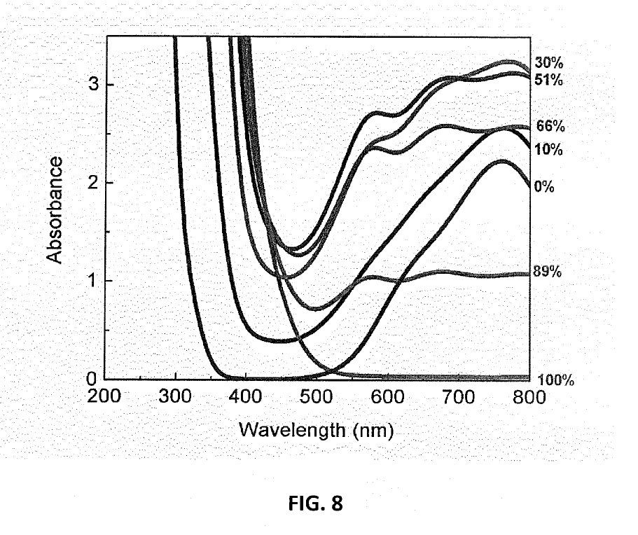

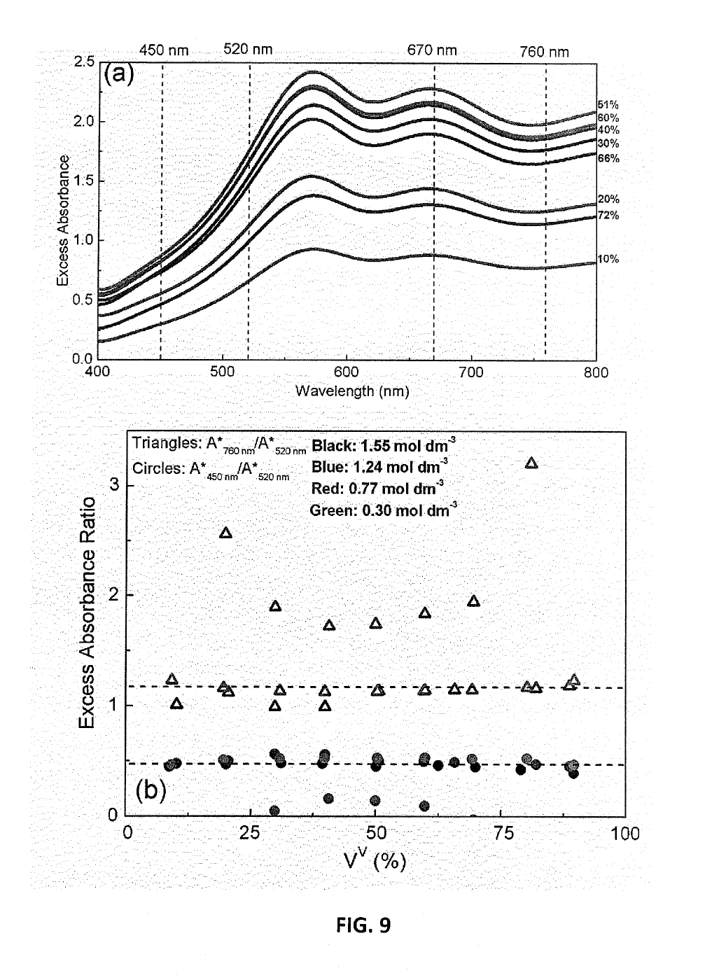

In cases, where the overall vanadium concentration is unknown or it is decided to verify or calibrate the system knowledge about the complex can facilitate the determination of vanadium concentration and determination of V^{V} fraction. For example, the absorbance for V^{IV} and V^{V} near 520 nm is almost the same and almost zero (see FIG. 8), i.e. there is an isosbestic point near this wavelength where both V^{IV} and V^{V} have the same low molar absorptivity. Therefore the vast majority of the absorbance at this wavelength for mixtures of V^{IV} and V^{V} at VRFB vanadium concentrations, as shown in FIGS. 7c and 8 is due to absorbance by the complex. Furthermore the excess absorbance caused by the presence of the complex (see FIG. 9) at any other wavelength can be calculated by multiplying the excess absorbance at 520 nm by a characteristic constant. The ratio of the excess absorbance at any two wavelengths is a constant for concentrations of 0.7 mol dm⁻³ or greater, independent of mixture ratio and total vanadium concentration as shown in FIG. 9b. The method allows the concentration of V^{IV} and V^{V} to be calculated separately and therefore the overall vanadium concentration and mixture ratio of the solution can be calculated without prior knowledge of the vanadium concentration. Therefore the excess absorbance at any wavelength can be calculated from the excess absorbance near 520 nm and therefore the absorbance due to just the V^{IV} and V^{V} species can be found. It follows that mixture ratio and overall vanadium concentration can be calculated.

FIG. 9a shows the excess absorbance values for 1.24 mol dm⁻³ mixtures as a function of wavelength. It can be observed that the ratio of excess absorbance at any two different wavelengths is almost constant (i.e. independent of mixture ratio). For instance, as shown in FIG. 9b, for 1.24 mol dm⁻³ mixture (blue), A*_{450 nm}/A*_{521 nm} (circles) is ˜0.5 and A*_{760 nm}/A*_{521 nm} (triangles) is ˜1.1 (where A*_{λ} is the excess absorbance value). Using the same method to analyse solutions of different overall vanadium concentration, it is found that, for 1.55 mol dm⁻³ (black) and 0.77 mol dm⁻³ (red) mixtures, these two ratios (A*_{450 nm}/A*_{521 nm} and A*_{760 nm}/A*_{521 nm}) are almost the same as the values calculated for the 1.24 mol dm⁻³ mixtures. However, it is also found that for the 0.30 mol dm⁻³ solution (green), these two ratios vary as mixture ratio changes. Therefore, for 0.77 mol dm⁻³ and above the ratios of excess absorbance are independent of both concentration and mixture ratio.

Using the following derivation, the mixture ratio and the concentrations of V^{IV} or V^{V} can be determined using the excess absorbance ratios. As an example, we will look at the values of absorbance for 1.24 mol dm⁻³ mixtures. Firstly, the excess absorbance can be calculated by subtracting the sum of V^{IV} and V^{V} absorbance values from the absorbance values for the solution at a given wavelength (as shown for each wavelength between 400 and 800 nm in FIG. 8a): i.e.

A*_{λ}=A_{λ}−ε_{λ}^{V}^{^{IV}}[V^{IV}]L−ε_{λ}^{V}^{^{V}}[V^{V}]L (1)

where [V^{IV}] and [V^{V}] are the V^{IV} and V^{V} concentration, respectively, before the formation of a complex, L is the pathlength of the light through the solution, and ε_{λ}^{V}^{^{IV}} and ε_{λ}^{V}^{^{V}} are the extinction coefficients for the V^{IV} and V^{V} species, respectively, at the wavelength (λ) of interest

Since the extinction coefficient at 760 nm due to V^{V}, ε_{760 nm}^{V}^{^{V}}, is almost zero, the absorbance at 760 nm for the mixture is mainly composed of the excess absorbance and V^{IV} absorbance. It follows from Eq. (1) that:

A_{760 nm}≈δ*_{760 nm}L+ε_{760 nm}^{V}^{^{IV}}[V^{IV}]L (2)

where δ*_{760 nm} is a constant that is dependent on the extinction coefficient and the concentration of the complex.

Similarly, since at the isosbestic (crossover) point of the V^{IV} and V^{V} spectra (near 520 m) both ε_{520 nm}^{V}^{^{IV}} and ε_{520 nm}^{V}^{^{V}} are almost the same, the variation of absorbance at 520 nm as a function of the fraction of V^{V} is solely due to the variation in complex concentration (for constant overall vanadium concentration). It follows from Eq. (1) that:

A_{520 nm}≈ε*_{520 nm}L+ε_{520 nm}^{V}([V^{IV}]+[V^{IV}])L (3)

where δ_{520 nm} is similar and directly proportional to the respective constant in Eq. (2) but for 520 nm and ε_{520 nm}^{V} is the extinction coefficient of V^{IV} and V^{V} at 520 nm. It should be noted that the extinction coefficient of the complex and the concentration of the complex is difficult to determine and the equilibrium constant K for the formation of the complex, where [complex]=K[V^{IV}]_{eq}[V^{V}]_{eq}, is unknown. However, equations 2 and 3 can be combined as:

$${A}_{760 nm} \approx \frac{{δ}_{760 nm}^{*} ( {A}_{520 nm} - {ε}_{520 nm}^{V} ( [ {V}^{IV} ] + [ {V}^{IV} ] ) L )}{{δ}_{520 nm}^{*}} + {ε}_{760 nm}^{{V}^{IV}} [ {V}^{IV} ] L \qquad ( 4 )$$

where δ*_{760 nm}/δ*_{520 nm} is equal to

$$\frac{{A}_{760 nm}^{*}}{{A}_{520 nm}^{*}} .$$

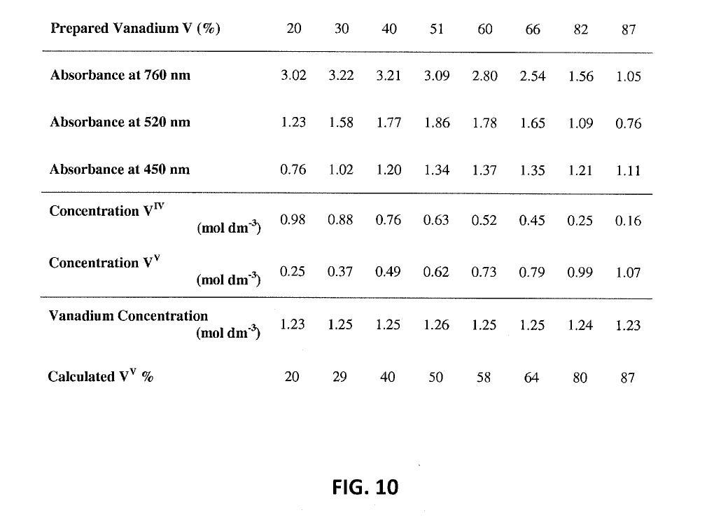

In a similar manner an equation for the absorbance at 450 nm can be derived with respect to [V^{V}]. (Furthermore, the absorbance at any number of couples of wavelengths can be chosen to derive similar equations.) It follows that by measuring the absorbance at three wavelengths, two equations with two unknowns, [V^{IV}] and [V^{V}], can be formed and therefore solved, as shown in FIG. 10.

FIG. 10 shows the calculated species concentrations for solutions of different mixture ratio, but the same overall vanadium concentration (1.24 mol dm⁻³). Using the absorbance values shown for V^{IV}/V^{V} mixtures in FIG. 8 the fraction of V^{V} ([V^{V}]/([V^{IV}]+[V^{V}])) along with the overall vanadium concentration were calculated. The method can achieve very good estimates for both the mixture ratio and overall vanadium concentration.

This technique can be used in conjunction with other methods for determining the V^{IV}, V^{V} or total vanadium concentration allowing these three concentrations to be estimated from the absorbance at two or more wavelengths. Furthermore, wavelengths other than the three chosen here can be used.

Alternatively, overall vanadium concentration can be determined from observing the change in absorbance at any wavelength (or several wavelengths) while charging or discharging the electrolyte (or an aliquot of the electrolyte). This technique also relies on the excess absorbance being dependent on a characteristic constant (B=ε_{λ}*KL) for each wavelength. It follows that the absorbance at wavelengths greater than 520 nm, e.g. at 760 nm can be written as

$${A}_{760 nm} = - {B ( \frac{[ {V}^{IV} ]}{[ V ]} )}^{2} + B ( \frac{[ {V}^{IV} ]}{[ V ]} ) + C \frac{[ {V}^{IV} ]}{[ V ]} + D \qquad ( 5 )$$

Where B, C and D are constants. Therefore the change in absorbance with charge or V^{IV} concentration can be written as

$$\frac{d {A}_{760 nm}}{d [ {V}^{IV} ]} = - \frac{2 B}{{[ V ]}^{2}} [ {V}^{IV} ] + \frac{B + C}{[ V ]} \qquad ( 6 )$$

This results in a straight-line graph when

$$\frac{d {A}_{760 nm}}{d {V}^{IV}}$$

is plotted against V^{IV} concentration or change in V^{IV} concentration. The slope of the graph is

$$- \frac{2 B}{{[ V ]}^{2}}$$

and therefore the total vanadium concentration can be calculated during a short charge/discharge of a known volume of positive electrolyte. Once this has been determined the V^{V} fraction (i.e. the SoC) of the positive electrolyte can then be determined, as explained earlier (see FIG. 2) or by imputing the V^{IV} or V^{V} concentration into Eq. (4) or a similar equation.

Alternative mathematical manipulation of the quadratic relationship between the concentration of the complex (i.e. the excess absorbance due to the complex) and the concentration of V^{IV} or V^{V} in mixture solutions other than those shown here can also be used to achieve values for the concentrations of V^{IV} and/or V^{V} from the absorbance at one or more wavelengths. Furthermore, in conjunction with part or all of one of the techniques previously described the V^{IV} or V^{V} concentration or the V^{IV} or V^{V} fraction estimated from the manipulation of the quadratic relationship can be used to find the concentrations of V^{IV}, V^{V} and total vanadium.

In addition these techniques can be extended to analytical devices that use optical characteristics of vanadium solutions other than transmittance and absorbance, such as reflection, refraction, total internal reflection etc.

It will be appreciated that the above described methods have a number of advantages over the prior art methods of determining the mixture ratio of vanadium solutions. Firstly, they allow the mixture ratios and hence state of charge of the two half cells to be measured independently of each other and independently of the electrochemistry of the system. In addition they allow the mixture ratio of the respective electrolyte to be measured in situ and both the vanadium concentration and the mixture ratio to be determined, which is very important in real systems. This is because it is important to not have to rely on the original vanadium concentration, as the volume (and therefore the concentration) of the electrolyte can vary due to evaporation of solution from the system, or transfer of solution species across the membrane. Indeed, the transfer of solution species can also result in the total number of moles of vanadium (and therefore the concentration) changing in the reservoirs during experiments.

The embodiments in the invention described with reference to the drawings comprise of look-up charts and calculations. However, the invention also extends to computer apparatus and/or processes performed in a computer apparatus, computer programs, particularly computer programs stored on or in a carrier adapted to bring the invention into practice. The program may be in the form of source code, object code, or a code intermediate source and object code, such as in partially compiled form or in any other form suitable for use in the implementation of the method according to the invention. The carrier may comprise a storage medium such as ROM, e.g. CD ROM, or magnetic recording medium, e.g. a floppy disk or hard disk. The carrier may be an electrical or optical signal which may be transmitted via an electrical or an optical cable or by radio or other means.

In the specification the terms “comprise, comprises, comprised and comprising” or any variation thereof and the terms include, includes, included and including” or any variation thereof are considered to be totally interchangeable and they should all be afforded the widest possible interpretation and vice versa.

The invention is not limited to the embodiments hereinbefore described but may be varied in both construction and detail.

1. A method for determining V^{IV} or V^{V} concentration in a mixture of V^{IV} and V^{V} solution, the method comprising the steps of:
determining the absorbance of the solution at least one wavelength; and
calculating the concentration of the V^{IV} and/or V^{V} solution based on the absorbance.

2. The method of claim 1, wherein the overall vanadium concentration in the solution is known and where a non-proportional relationship exists between the vanadium species concentration and absorbance due to the presence of complexes between V^{IV} and V^{V}, wherein the step of calculating the concentration of the V^{IV} and/or V^{V} solution based on the absorbance comprises the steps of:
comparing the absorbance against a look-up graph of absorbance versus fraction of V^{V} for at least one wavelength and for the same overall vanadium concentration; and
estimating the fraction of V^{IV} and/or V^{V} in the solution from the comparison.

3. The method of claim 2 further comprising:
determining the absorbance of the solution at least one alternative wavelength;
comparing the absorbance against a look-up graph of absorbance versus fraction of V^{V} for the at least one alternative wavelength and for the same overall vanadium concentration; and
estimating the fraction of V^{IV} and/or V^{V} in the solution from the comparison performed at the at least one wavelength and the comparison performed at the at least one alternative wavelength.

4. The method of claim 2 further comprising estimating the fraction of V^{IV} and/or V^{V} in the solution from the comparison performed at the at least one wavelength and based on one or more of: positive state of charge, SoC, negative SoC, cell voltage or the change in absorbance when charging or discharging of the electrolyte.

5. The method of claim 2, wherein the look-up graph of absorbance versus fraction of V^{V} for a given wavelength is constructed by the steps of:
determining for the given wavelength the absorbance of a V^{IV} solution of a known concentration; and
determining for the given wavelength the absorbance of a calibration sample of V^{IV}/V^{V} solution of a known mixture ratio and a known concentration.

6. The method of claim 5, wherein two calibration samples of V^{IV}-V^{V} mixtures of known concentration and mixture ratio are used for the construction of the look-up graph.

7. The method of claim 5, wherein a solution whose V^{IV}/V^{V} mixture ratio can be changed in a controlled manner is used for calibration, and wherein the calibration comprises changing the mixture ratio and comparing the change in mixture ratio to the absorbance of the solution.

8. (canceled)

9. The method of claim 1, wherein the overall vanadium concentration is known and where a non-proportional relationship exists between vanadium species concentration and absorbance due to the presence of complexes between V^{IV} and V^{V}, wherein the step of calculating the concentration of the V^{IV} and/or V^{V} solution based on the absorbance comprises the steps of:
determining the ratio of excess absorbance for a pair of specific wavelengths; and
estimating the concentration of V^{IV} and/or V^{V} by solving simultaneous equations based on the determined ratio of excess absorbance for the pair of specific wavelengths.

10. The method of claim 1, wherein the overall vanadium concentration is not known and, wherein the concentration of vanadium or the concentration of the V^{IV} and/or V^{V} solution is calculated by:
determining the ratio of excess absorbance for two pairs of specific wavelengths; and
estimating the concentration of vanadium, V^{IV} and/or V^{V} by solving simultaneous equations based on the determined ratio of excess absorbance for the two pairs of specific wavelengths.

11. The method of claim 9, wherein the equation for the simultaneous equations comprises
$${A}_{y nm} \approx \frac{{δ}_{y nm}^{*} ( {A}_{x nm} - {ε}_{x nm}^{V} ( [ {V}^{IV} ] + [ {V}^{IV} ] ) L )}{{δ}_{x nm}^{*}} + {ε}_{y nm}^{{V}^{IV}} [ {V}^{IV} ] L$$
where A_{y nm} is absorbance at y nanometres and A_{x nm} is the absorbance at x nanometres, δ is a constant that is dependent on the extinction coefficient and the concentration of the complex, ε_{λ}^{V}^{^{IV}} and ε_{λ}^{V}^{^{V}} are the extinction coefficients for the V^{IV} and V^{V} species, respectively, at the wavelength (λ) of interest, [V^{IV}] and [V^{V}] are the V^{IV} and V^{V} concentration, respectively, before the formation of a complex, and L is the pathlength of the light through the solution

12. The method of claim 9, wherein the excess absorbance at a specific wavelength is determined by:
measuring the absorbance at a specific wavelength of a solution of known vanadium concentration;
calculating the predicted absorbance at the specific wavelength that would occur if no complexes were present; and
subtracting this calculated predicted absorbance value from the measured absorbance value.

13-15. (canceled)

16. The method of claim 2, wherein the absorbance of the solution at least one alternative wavelength is used to determine or verify the fraction or concentration of either V^{IV} or V^{V}.

17. A method for calculating the state of charge, SoC, of a vanadium redox flow battery, VRFB, comprising a V^{II}-V^{III}-solution and a V^{IV}-V^{V} solution, the method comprising the steps of:
calculating the amount of V^{V} in the V^{IV}-V^{V} solution by the method of claim 1;
calculating the amount of V^{II} in the V^{II}-V^{III} solution;
determining whether the calculated amount of V^{V} or the calculated amount of V^{II} is lower in value; and
determining the SoC of the VRFB from this lower value.

18. The method of claim 17 for calculating the SoC of an electrochemical cell comprising of a V^{IV} and V^{V} solution as the catholyte or anolyte in one half of the cell and a second half-cell whose remaining charge can be estimated.

19. The method of claim 1 when used for a group of electrochemical cells of the same type either in series or in parallel.

20. The method of claim 1 when used for electrochemical cells of different types either in series or in parallel where some or all of the half-cells use mixtures of V^{IV} and V^{V} in solution.
